(19) United States
(12) Patent Application Publication
(10) Pub. No.: US 2025/0294727 A1
(43) Pub. Date: Sep. 18, 2025

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Erh-Kun LAI, Taichung County (TW); Feng-Min LEE, Hsinchu City (TW)

(21) Appl. No.: 18/605,974

(22) Filed: Mar. 15, 2024

(51) Int. Cl. H10B 12/00

(52) U.S. Cl. CPC H10B 12/488; H10B 12/05; H10B 12/482

(57) ABSTRACT

A semiconductor structure and a method for manufacturing a semiconductor structure are provided. The semiconductor structure includes conductive layers, a first gate pillar penetrating the conductive layers, a first channel element surrounding the first gate pillar, a first conductive strip on a sidewall of the first channel element, and a charge storage structure on a surface of the first conductive strip.

### BACKGROUND

### Technical Field

The disclosure relates to a semiconductor structure and a method for manufacturing the same, and more particularly to a three-dimensional semiconductor structure and a method for manufacturing the same.

### Description of the Related Art

Due to improvements in circuit design, materials and manufacturing processes, the size of two-dimensional semiconductor structure has been significantly reduced in the past few decades. The smaller the size of the two-dimensional semiconductor structure, the higher the challenge faced by the manufacturing process, which causing the size reduction of the two-dimensional semiconductor structure has faced technical obstacles. Changing the semiconductor structure from a two-dimensional architecture to a three-dimensional architecture is one of the most promising solutions for overcoming the technical problems faced by the two-dimensional semiconductor structure. However, most three-dimensional semiconductor structures still face some electrical problems. There is still a need to provide an improved three-dimensional semiconductor structure and a method for manufacturing the same.

### SUMMARY

According to an embodiment of the present disclosure, a semiconductor structure is provided. The semiconductor structure includes conductive layers, a first gate pillar penetrating the conductive layers, a first channel element surrounding the first gate pillar, a first conductive strip on a sidewall of the first channel element, and a charge storage structure on a surface of the first conductive strip.

According to an embodiment of the present disclosure, a method for manufacturing a semiconductor structure is provided. The method includes: forming a first stack and s second stack, wherein the second stack is on a sidewall of the first stack; forming a channel element in the first stack; forming a gate pillar in the first stack, wherein the channel element surrounds the gate pillar; forming bit lines, wherein the gate pillar penetrating the bit lines; forming a conductive strip on a sidewall of the channel element; forming a charge storage structure on a surface of the conductive strip.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1A illustrates a schematic top view of a semiconductor structure according to an embodiment of the present disclosure.

FIG. 1B illustrates a schematic top view of the semiconductor structure of FIG. 1A.

FIG. 1C illustrates a cross-sectional view of the semiconductor structure of FIG. 1A.

FIG. 2A illustrates a schematic top view of a semiconductor structure according to another embodiment of the present disclosure.

FIG. 2B illustrates a schematic top view of the semiconductor structure of FIG. 2A.

FIG. 2C illustrates a cross-sectional view of the semiconductor structure of FIG. 2A.

FIG. 3 illustrates a schematic top view of a semiconductor structure according to an embodiment of the present disclosure.

FIGS. 4A to 10C illustrate a method for manufacturing a semiconductor structure according to an embodiment of the present disclosure.

FIGS. 11A to 14C illustrate a method for manufacturing a semiconductor structure according to an embodiment of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation.

The embodiments according to the present disclosure can be applied to many different types of three-dimensional semiconductor structures. For example, the embodiments can be applied to, but not limited to, three-dimensional semiconductor structures including dynamic random-access memories (DRAM).

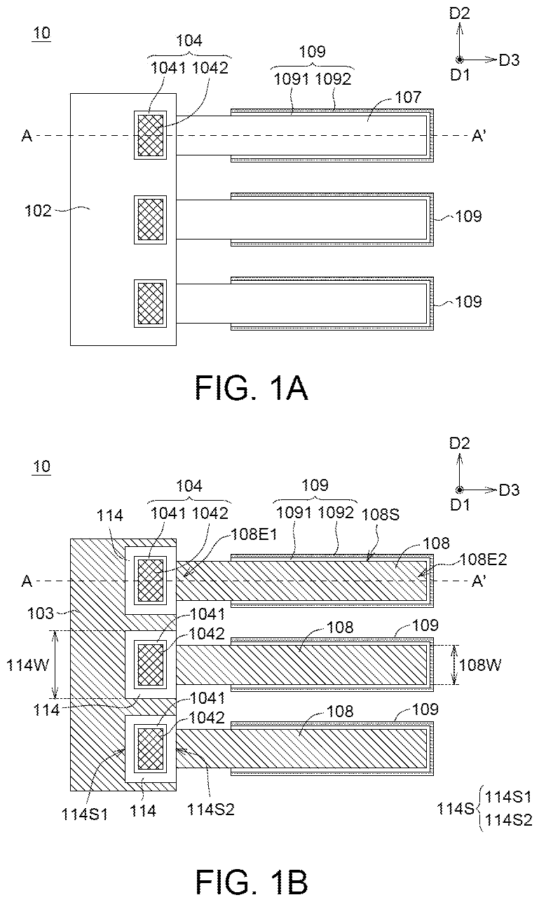

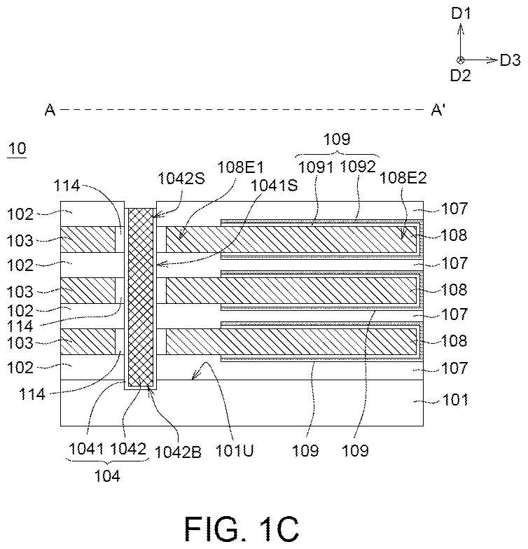

Referring to FIGS. 1A to 1C, FIG. 1A illustrates a schematic top view of a semiconductor structure 10 according to an embodiment of the present disclosure, FIG. 1B illustrates a schematic top view of the semiconductor structure 10 of FIG. 1A, corresponding to a plane of a conductive layer 103, and FIG. 1C is a cross-sectional view of the semiconductor structure 10 illustrated along the lines AA′ shown in FIGS. 1A to 1B. The semiconductor structure 10 includes an insulating film 101, insulating layers 102, conductive layers 103, gate structures 104, channel elements 114, insulating strips 107, conductive strips 108, and charge storage structures 109. The insulating layers 102 and the conductive layers 103 are stacked alternately along a first direction D1 and disposed on an upper surface 101U of the insulating film 101. The insulating film 101 may extend along a plane formed by a second direction D2 and a third direction D3. The insulating layers 102 may extend along the second direction D2. The conductive layers 103 may extend along the second direction D2. The conductive layers 103 are separated from each other by the insulating layers 102. The first direction D1, the second direction D2 and the third direction D3 are perpendicular to each other. The first direction D1 may be a direction of a normal to the upper surface 101U of the insulating film 101. FIG. 1C shows four insulating layers 102 and three conductive layers 103, but the present disclosure is not limited thereto. The semiconductor structure 10 may include more or less insulating layers 102 and conductive layers 103 which can be disposed on the insulating film 101 in a manner similar to that shown in FIG. 1C.

The gate structures 104 are separated from each other. The gate structures 104 may be disposed along the second direction D2 in the insulating layers 102 and the conductive layers 103. Each of the gate structures 104 extends along the first direction D1 and penetrates insulating layers 102 and conductive layers 103. In the present embodiment, an end portion of the gate structure 104 is in the insulating film 101, but the present disclosure is not limited thereto; the end portion of the gate structure 104 can be in the insulation layer 102. The gate structure 104 includes a dielectric layer 1041 and a gate pillar 1042. The dielectric layer 1041 may surround the gate pillar 1042. The dielectric layer 1041 may be disposed on a sidewall 1042S and a bottom surface 1042B of the gate pillar 1042. A portion of the dielectric layer 1041 is between the gate pillar 1042 and the insulating film 101. A portion of the dielectric layer 1041 is between the gate pillar 1042 and the insulating layer 102. A portion of the dielectric layer 1041 is between the gate pillar 1042 and the conductive layer 103. The gate pillars 1042 may be disposed along the second direction D2 in the insulating layers 102 and the conductive layers 103. The gate pillars 1042 may extend along the first direction D1 and penetrate the insulating layers 102 and the conductive layers 103. FIGS. 1A to 1B show that a cross section of the gate pillar 1041 in a plane formed by the second direction D2 and the third direction D3 is rectangular, but the present disclosure is not limited thereto. The cross section of the gate pillar 1041 in a plane formed by the second direction D2 and the third direction D3 may be rectangular, square, elliptical, circular or various other shapes. FIGS. 1A to 1B show three gate structures 104, but the present disclosure is not limited thereto. The semiconductor structure 10 may include more or less gate structures 104. The gate structure 104 is electrically connected to the conductive layers 103.

The channel elements 114 are separated from each other. The channel elements 114 may be disposed along the first direction D1 and the second direction D2 in the conductive layers 103. The conductive 103 may cover a portion of a sidewall 114S of the channel element 114, that is, the sidewall 114S of the channel element 114 may include a first sidewall portion 114S1 coved by the conductive layer 103 and a second sidewall portion 114S2 not covered by the conductive layer 103. The channel element 114 may surround the dielectric layer 1041 and the gate pillar 1042 of the gate structure 104. The channel element 114 may be on a sidewall 1041S of the dielectric layer 1041. The channel element 114 may be between the dielectric layer 1041 and the conductive layer 103. A portion of the dielectric layer 1041 may be between the gate pillar 1042 and the channel element 114. One channel element 114 may surround only one gate structure 104. One gate structure 104 may be surrounded by a plurality of the channel elements 114. For example, as shown in FIG. 1C, one gate structure 104 is surrounded by a plurality of the channel elements 114 disposed along the first direction D1. FIG. 1C shows that one gate structure 104 is surround by three channel elements 114, but the present disclosure is not limited thereto; one gate structure 104 may be surrounded by more or less channel elements 114. The channel element 114 may have a hollow columnar shape. The channel element 114 is electrically connected to the conductive layer 103 where this channel element 114 is disposed. The channel element 114 is electrically connected to the gate structure 104 surrounded by this channel element 114.

The conductive strips 108 are separated from each other and disposed on the upper surface 101U of the insulating film 101. The conductive strips 108 may be disposed along the first direction D1 and the second direction D2. Each of the conductive strips 108 extends along the third direction D3. Each of the conductive strips 108 includes a first end portion 108E1 and a second end portion 108E2 separated from the first end portion 108E1. The first end portion 108E1 and the second end portion 108E2 of the conductive strip 108 are respectively at opposite ends of the conductive strip 108 along the third direction D3. The conductive strip 108 may be disposed on the second sidewall portion 114S2 of the sidewall 114S of the channel element 114, and electrically connected to this channel element 114. The first end portion 108E1 of the conductive strip 108 may connect or contact the second sidewall portion 114S2 of the sidewall 114S of the channel element 114. A maximum width 108W of the conductive strip 108 in the second direction D2 may be less than or equal to a maximum width 114W of the channel element 114 in the second direction D2. In an embodiment, the channel elements 114 and the conductive strips 108 may have a one-to-one correspondence, that is, a channel element 114 and a conductive strip 108 corresponding to and/or electrically connected to this channel element 114 may be disposed at the same height (or level) in the first direction D1. In an embodiment, the channel elements 114, the conductive strips 108 and the conductive layer 103 may have a correspondence, that is, a channel element 114 and a conductive strip 108 corresponding to and/or electrically connected to this channel element 114, and a conductive layer 103 corresponding to and/or electrically connected to this channel element 114 may be disposed at the same height (or level) in the first direction D1.

The insulating strips 107 are separated from each other and disposed on the upper surface 101U of the insulating film 101. The insulating strips 107 may be disposed along the first direction D1 and the second direction D2. Each of the insulating strips 107 extends along the third direction D3. The insulating strips 107 and the conductive strips 108 may be stacked alternately along the first direction D1 on the upper surface 101U of the insulating film 101. The conductive strips 108 are separated from each other by the insulating strips 107. The insulating strip 107 may be disposed on the sidewall of the insulating layer 102.

The charge storage structures 109 are separated from each other by the insulating strips 107. The charge storage structure 109 may be disposed on a surface 108S of the conductive strip 108. The charge storage structure 109 may surround a portion of the conductive strip 108. The charge storage structure 109 may surround or cover the second end portion 108E2 of the conductive strip 108. The charge storage structure 109 may not surround or cover the first end portion 108E1 of the conductive strip 108. The charge storage structure 109 may be separated from the channel element 114. The charge storage structure 109 is electrically connected to the conductive strip 108 surrounded by this charge storage structure 109. Each of the charge storage structure 109 may include a dielectric element 1091 and a conductive element 1092. The dielectric element 1091 is between the conductive element 1092 and the conductive strip 108. The dielectric element 1091 may be disposed on the surface 108S of the conductive strip 108. The conductive element 1092 may be disposed on the outer surface of the conductive strip 108. In other embodiment, the conductive elements 1092 disposed along the first direction D1 (i.e. the conductive elements 1092 corresponding to the same gate structure 104) may be connected to each other, and thus the semiconductor structure 10 may not include insulating strips 107 between these conductive elements 1092.

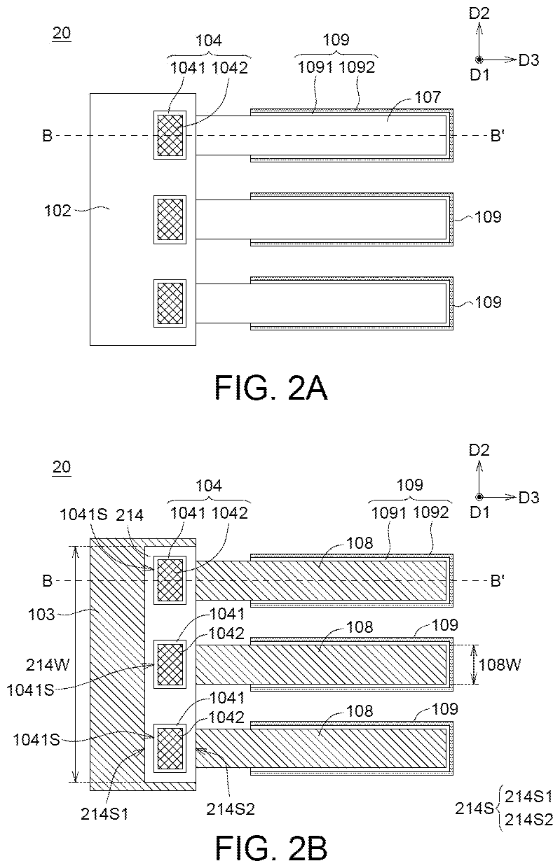

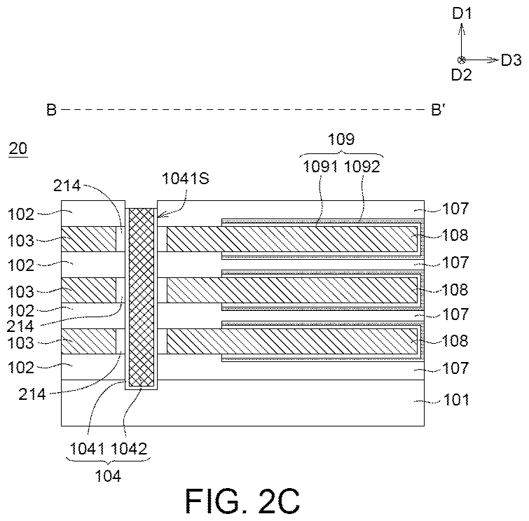

Referring to FIGS. 2A to 2C, FIG. 2A illustrates a schematic top view of a semiconductor structure 20 according to another embodiment of the present disclosure, FIG. 2B illustrates a schematic top view of the semiconductor structure 20 of FIG. 2A, corresponding to a plane of a conductive layer 103, and FIG. 2C is a cross-sectional view of the semiconductor structure 20 illustrated along the lines BB′ shown in FIGS. 2A to 2B. Among FIGS. 1A to 2C, identical reference numerals correspond to identical elements which have identical properties, and descriptions of these repeated elements are omitted below. The differences between the semiconductor structure 20 and the semiconductor structure 10 are that, the semiconductor structure 20 includes channel elements 214 and each of the channel elements 214 surrounds a plurality of the gate structures 104.

The channel elements 214 may extend along a plane formed by the second direction D2 and the third direction D3 and surround the gate structures 104 disposed along the second direction D2. FIG. 2C shows that one channel element 214 surround three gate structures 104, but the present disclosure is not limited thereto; one channel element 214 can surround more or less gate structures 104. The channel element 214 may be disposed on the sidewalls 1041S of the dielectric layers 1041. A portion of the channel element 214 is between the dielectric layer 1041 and the conductive layer 103. A portion of the channel element 214 is between the dielectric layer 1041 and the conductive strip 108. The channel elements 214 may be disposed along the first direction D1 in the conductive layers 103. The channel elements 214 are separated from each other in the first direction D1 by the insulating layers 102. The conductive 103 may cover a portion of a sidewall 214S of the channel element 214, that is, the sidewall 214S of the channel element 214 may include a first sidewall portion 214S1 coved by the conductive layer 103 and a second sidewall portion 214S2 not covered by the conductive layer 103. In the present embodiment, the conductive strips 108 at the same level (or the conductive strips 108 disposed at the same height in the first direction D1) are disposed on the second sidewall portion 214S2 of the sidewall 214S of the channel element 214, and these conductive strips 108 are electrically connected to this channel element 214.

One gate structure 104 can be surrounded by a plurality of the channel elements 214. For example, as shown in FIG. 2C, one gate structure 104 is surrounded by a plurality of the channel elements 214 disposed along the first direction D1. FIG. 2C shows that one gate structure 104 is surround by three channel elements 214, but the present disclosure is not limited thereto; one gate structure 104 may be surrounded by more or less channel elements 214. The channel element 214 is electrically connected to the conductive layer 103 where this channel element 214 is disposed. The channel element 214 is electrically connected to the gate structures 104 surrounded by this channel element 214. In the semiconductor structure 20, the maximum width 108W of the conductive strip 108 in the second direction D2 is less than a maximum width 214W of the channel element 214 in the second direction D2.

The semiconductor structure 10/20 may include transistors and capacitors. The transistors are formed at the intersections of the conductive layers 103 and the conductive strips 108. The conductive strips 108, the dielectric elements 1091 of the charge storage structures 109, and the conductive elements 1092 of the charge storage structures 109 can form (or can be functioned as) capacitors. One transistor and one capacitor (1T1C) may form a memory cell. The semiconductor structure 10/20 may include memory cells. The conductive layers 103 are functioned as bit lines. The gate structures 104 are functioned as word lines. The transistor includes a first drain/source terminal, a second drain/source terminal and a gate terminal. The capacitor includes a first terminal and a second terminal. The first drain/source terminal of the transistor is electrically connected to the bit line. The second drain/source terminal of the transistor is electrically connected to the first terminal of the capacitor. The gate terminal of the transistor is electrically connected to the word line. The second terminal of the capacitor is electrically connected to a source line. In an embodiment, the first terminal of the capacitor is electrically connected to the conductive strip 108, and the second terminal of the capacitor is electrically connected to ground. The transistors can be selectively turned on or turned off to selectively operate the capacitor. In an embodiment, a large amount of charge can be stored in the dielectric element 1091 of the charge storage structure 109 (or can be understood as charging the capacitor) to represent a logical “1”, or a small amount of charge can be stored in the dielectric element 1091 of the charge storage structure 109 (or can be understood as discharging the capacitor) to represent a logical “0”. In an embodiment, the memory cells of the semiconductor structure 10/20 can be dynamic random-access memory cells, and the semiconductor structure 10/20 can include a dynamic random-access memory device or can be a dynamic random-access memory device.

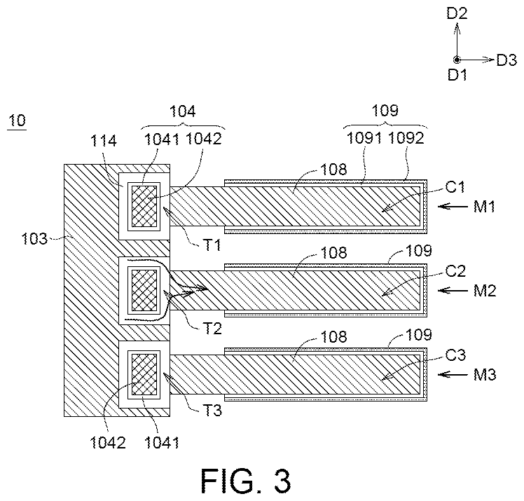

One of the operations which can be performed in the semiconductor structure according to the present disclosure will be exemplarily described below with reference to FIG. 3. FIG. 3 illustrates a schematic top view of the semiconductor structure 10 according to an embodiment of the present disclosure. The semiconductor structure 10 may include a transistor T1 formed at the intersection of the conductive layer 103 and the upper conductive strip 108 shown in FIG. 3, a transistor T2 formed at the intersection of the conductive layer 103 and the middle conductive strip 108 shown in FIG. 3, and a transistor T3 formed at the intersection of the conductive layer 103 and the lower conductive strip 108 shown in FIG. 3. The semiconductor structure 10 may include a capacitor C1, a capacitor C2 and a capacitor C3. The upper conductive strip 108 shown in FIG. 3 and a charge storage structure 109 on the surface of this conductive strip 108 form the capacitor C1. The middle conductive strip 108 shown in FIG. 3 and a charge storage structure 109 on the surface of this conductive strip 108 form the capacitor C2. The lower conductive strip 108 shown in FIG. 3 and a charge storage structure 109 on the surface of this conductive strip 108 form the capacitor C3. The transistor T1 and the capacitor C1 electrically to the transistor T1 form a memory M1. The transistor T2 and the capacitor C2 electrically to the transistor T2 form a memory M2. The transistor T3 and the capacitor C3 electrically to the transistor T3 form a memory M3. In an operation, a bit line bias voltage is applied to the conductive layer 103, a first source line bias voltage is applied to a source line electrically connected to the capacitor C1, a first source line bias voltage is applied to a source line electrically connected to the capacitor C3, a second source line bias voltage is applied to a source line electrically connected to the capacitor C2, a first word line bias voltage is applied to the upper gate structure 104 shown in FIG. 3 to turn off the transistor T1 (e.g. turn off the channel element 114 of the transistor T1), a first word line bias voltage is applied to the lower gate structure 104 shown in FIG. 3 to turn off the transistor T3 (e.g. turn off the channel element 114 of the transistor T3), a second word line bias voltage is applied to the middle gate structure 104 shown in FIG. 3 to turn on the transistor T2 (e.g. turn on the channel element 114 of the transistor T2); the memory cells M1 and M3 are unselected, and the memory cell M2 is selected for operating. For example, the capacitor C2 of the selected memory cell M2 can be charged or discharged. In some operations, the first word line bias voltage is different from the second word line bias voltage. When the transistor T2 is turned on, current can flow between the first drain/source terminal and the second drain/source terminal of the transistor T2. One of the possible current directions is indicated by arrows in FIG. 3. The operations of the semiconductor structure includes a Read operation, a Write operation and a Hold operation. The Write operation may include writing logical “1” and writing logical “0”.

Table 1 shows bias voltage configurations that can be used to operate the semiconductor structure according to the present disclosure. The conductive layers 103 of the semiconductor structure 10/20 may be electrically connected to a sense amplifier (SA). The term “selected word line” in Table 1 refers to a word line electrically connected to a selected memory cell, for example, the word line electrically connected to the memory cell M2 in FIG. 3. The term “unselected word line” in Table 1 refers to a word line electrically connected to a unselected memory cell, for example, the word line electrically connected to the memory cells M1 and M3 in FIG. 3. The term “selected bit line” in Table 1 refers to a bit line electrically connected to a selected memory cell, for example, the bit line electrically connected to the memory cell M2 in FIG. 3 (i.e. the conductive layer 103 corresponding to the memory cells M1, M2 and M3). The term “unselected bit line” in Table 1 refers to a bit line that is not electrically connected to the selected memory cell, for example, the bit line electrically connected to the memory cells located at different level than the memory cell M2 in FIG. 3 (for example, the conductive layer 103 located above or below the conductive layer 103 corresponding to the memory cells M1, M2 and M3 in the first direction D1).

TABLE 1

| | | Read | | Writing | | Writing | | Hold | |
|---|---|---|---|---|---|---|---|---|---|
| | | operation | | logical “0” | | logical “1” | | operation | |
| Word line | Selected | 1.5 | V | 1.5 | V | 1.5 | V | 0 | V |
| bias | word line | | | | | | | | |
| voltage | Unselected | 0 | V | 0 | V | 0 | V | 0 | V |
| | word line | | | | | | | | |
| Bit line | Selected | 0 | V | 1.3 | V | 0 | V | 0 | V |
| bias | bit line | | | | | | | | |
| voltage | Unselected | 0 | V | 0 | V | 0 | V | 0 | V |
| | bit line | | | | | | | | |
| Sense | | On | | Off | | Off | | Off | |
| amplifier | | | | | | | | | |

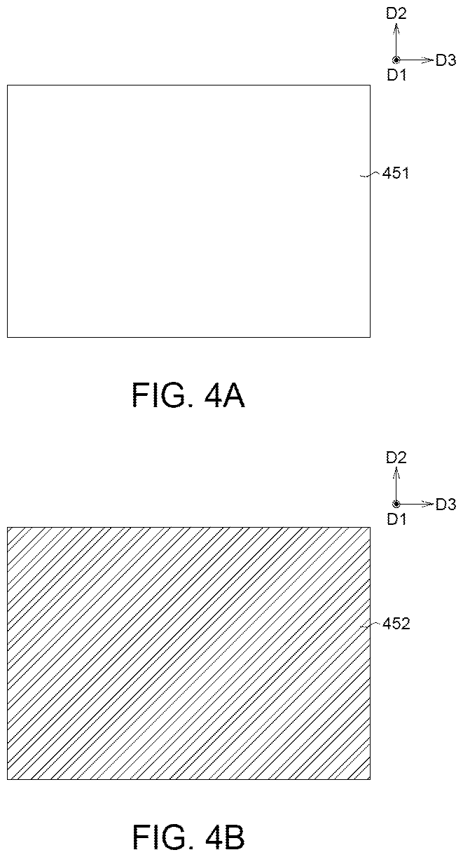

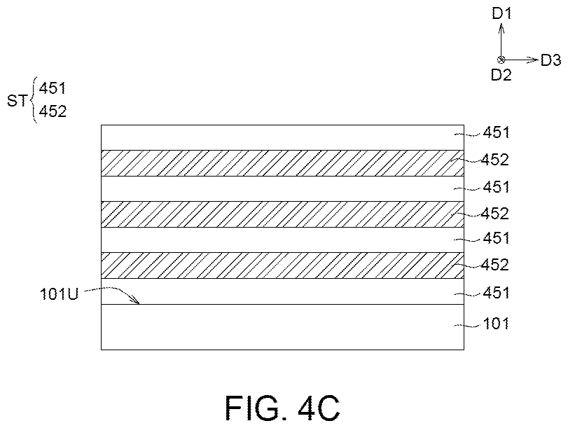

FIGS. 4A to 10C illustrate a method for manufacturing a semiconductor structure according to an embodiment of the present disclosure.

Referring to FIGS. 4A to 4C, FIG. 4A illustrates a schematic top view of a structure at a stage of the manufacturing method, FIG. 4B illustrates a schematic top view of the structure, corresponding to a plane of an insulating layer 452, at this stage of the manufacturing method, and FIG. 4C illustrates a cross-sectional view of the structure at this stage. An insulating film 101 is provided. A stack structure ST is formed on the insulating film 101. The stack structure ST includes insulating layers 451 and insulating layers 452 stacked alternately along the first direction D1 on the upper surface 101U of the insulating film 101. The insulating layers 451 are separated from each other by the insulating layers 452. FIGS. 4A to 4C show that the topmost layer and the bottommost layer of the stack structure ST are insulating layers 451, and show four insulating layers 451 and three insulating layers 452, but the present disclosure is not limited thereto. The number and arrangement of the insulating layers 451 and the insulating layers 452 can be adjusted freely. The topmost insulating layer 451 of the stack structure ST can be used as a hard mask. The insulating layer 451 and the insulating layer 452 may include different materials. The insulating film 101 may include an insulating material including oxide, for example, the insulating film 101 includes silicon oxide. The insulating layer 451 may include an insulating material including oxide, for example, the insulating layer 451 includes silicon oxide. The insulating layer 452 may include an insulating material including nitride, for example, the insulating layer 452 includes silicon nitride. In an embodiment, the insulating layer 451 is a silicon oxide layer, and the insulating layer 452 is a silicon nitride layer. In an embodiment, the stack structure ST is formed by forming the insulating layers 451 and the insulating layers 452 alternately on the upper surface 101U of the insulating film 101 through a deposition process.

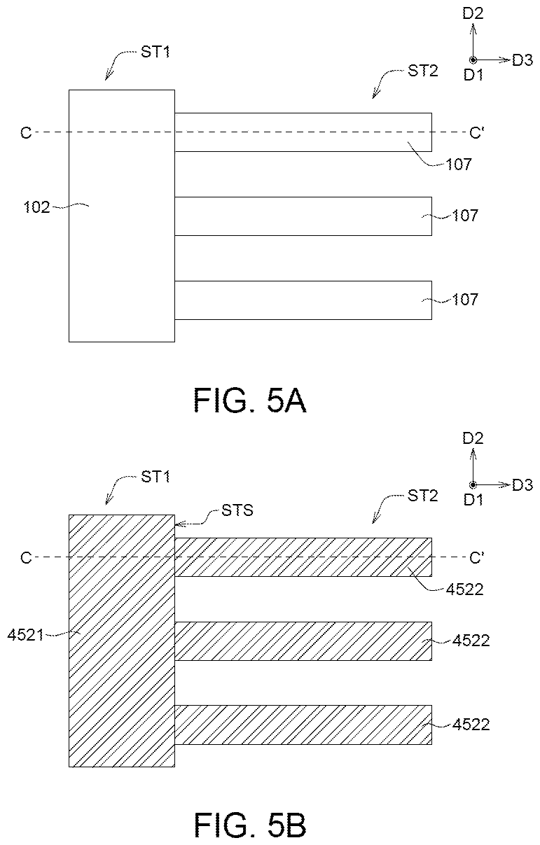

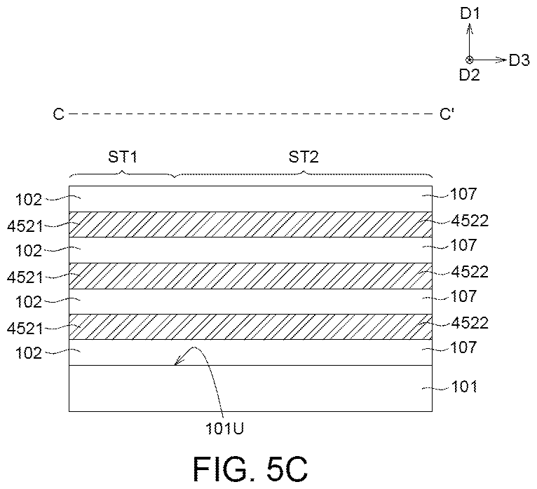

Referring to FIGS. 5A to 5C, FIG. 5A illustrates a schematic top view of a structure at a stage of the manufacturing method, FIG. 5B illustrates a schematic top view of the structure, corresponding to a plane of an insulating layer 4521 and an insulating strip 4522, at this stage of the manufacturing method, and FIG. 5C is a cross-sectional view of the structure at this stage illustrated along the lines CC′ shown in FIGS. 5A to 5B. A portion of the insulating layers 451 and a portion of the insulating layers 452 are removed to form a first stack ST1 and second stacks ST2. The second stacks ST2 is on an sidewall STS of the first stack ST1. The second stacks ST2 may adjoin the first stack ST1. The first stack ST1 and the second stack ST2 may be disposed along the third direction D3. The second stacks ST2 may be disposed along the second direction D2. The second stack ST2 may extend along the third direction D3. The first stack ST1 includes insulating layers 102 and insulating layers 4521 stacked alternately along the first direction D1 on the upper surface 101U of the insulating film 101. Each of the second stack ST2 includes insulating strips 107 and insulating strips 4522 stacked alternately along the first direction D1 on the upper surface 101U of the insulating film 101. In the present embodiment, the insulating layer 102 of the first stack ST1 and the insulating strip 107 of the second stack ST2 may have a one-to-one correspondence, that is, an insulating layer 102 and insulating strip 107 corresponding to this insulating layer 102 may be disposed at the same height (or level) in the first direction D1. In the present embodiment, the insulating layer 4521 of the first stack ST1 and the insulating strip 4522 of the second stack ST2 may have a one-to-one correspondence, that is, an insulating layer 4521 and insulating strip 4522 corresponding to this insulating layer 4521 may be disposed at the same height (or level) in the first direction D1. The insulating layer 102 is a part of the insulating layer 451. The insulating strip 107 is a part of the insulating layer 451. The insulating layer 4521 is a part of the insulating layer 452. The insulating strip 4522 is a part of the insulating layer 452. In an embodiment, a portion of the insulating layers 451 and a portion of the insulating layers 452 are removed through a photolithography process to form the first stack ST1 and the second stacks ST2.

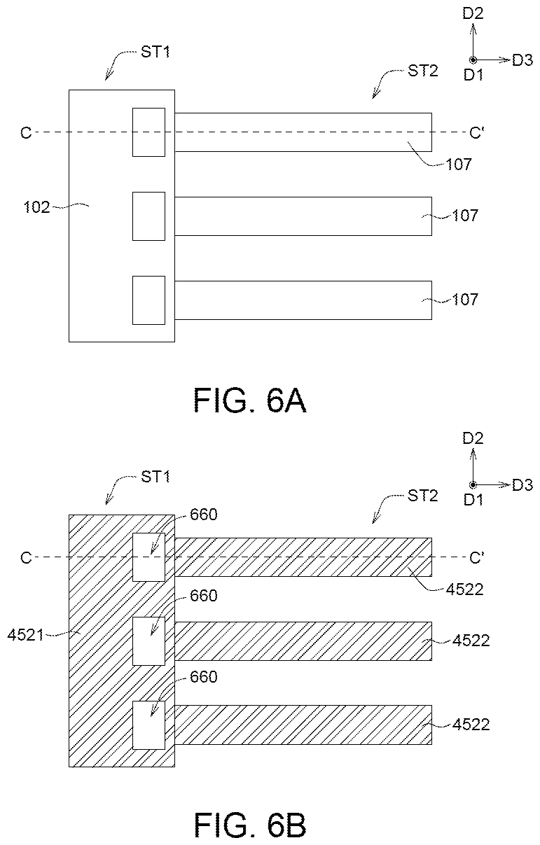

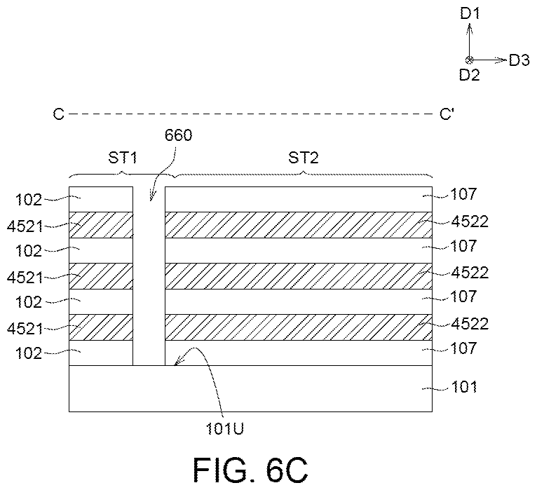

Referring to FIGS. 6A to 6C, FIG. 6A illustrates a schematic top view of a structure at a stage of the manufacturing method, FIG. 6B illustrates a schematic top view of the structure, corresponding to a plane of an insulating layer 4521 and an insulating strip 4522, at this stage of the manufacturing method, and FIG. 6C is a cross-sectional view of the structure at this stage illustrated along the lines CC′ shown in FIGS. 6A to 6B. Holes 660 are formed in the first stack ST1. The holes 660 are separated from each other. The holes extend along the first direction D1, penetrate the insulating layers 102 and the insulating layers 4521 of the first stack ST1, and stop at the insulating film 101. The sidewall of the first stack ST1, and the upper surface 101U of the insulating film 101 are exposed by the hole 660. The hole 660 may have any shape such as a cylindrical, elliptical cylindrical or square columnar shape. Each of the holes 660 may overlap a second stacks ST2. In an embodiment, a portion of the insulating layers 102 and a portion of the insulating layers 4521 are removed through a photolithography process to form the holes 660.

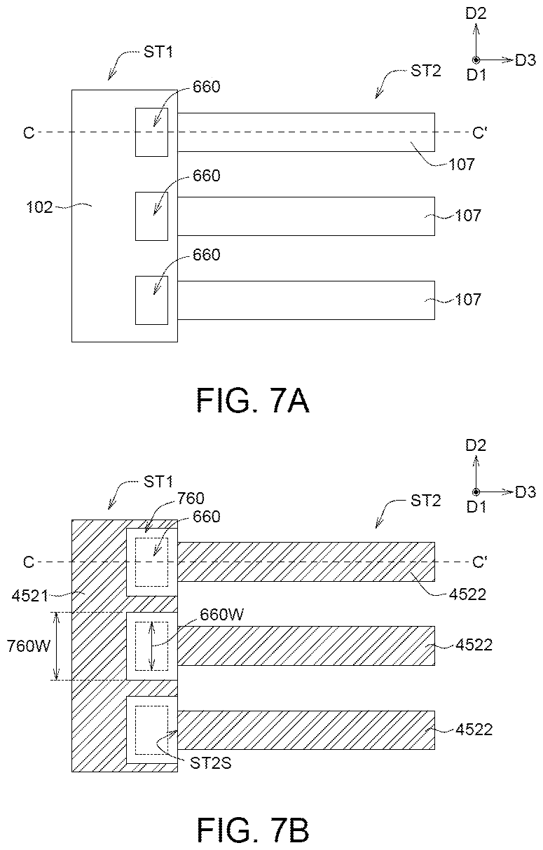

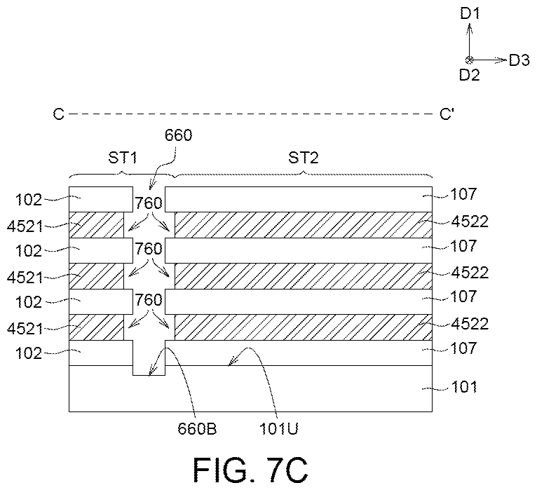

Referring to FIGS. 7A to 7C, FIG. 7A illustrates a schematic top view of a structure at a stage of the manufacturing method, FIG. 7B illustrates a schematic top view of the structure, corresponding to a plane of an insulating layer 4521 and an insulating strip 4522, at this stage of the manufacturing method, and FIG. 7C is a cross-sectional view of the structure at this stage illustrated along the lines CC′ shown in FIGS. 7A to 7B. A portion of the insulating layers 4521 is removed to form recesses 760. The recesses 760 are between the insulating layers 102. Each of the recesses 760 communicates with the hole 660. In the present embodiment, the recesses 760 disposed along the first direction D1 communicate with one hole 660. The recess 760 may be an annular recess surrounding the hole 660. A maximum width 760W of the recess 760 in the second direction D2 may be greater than a maximum width 660W of the hole 660 in the second direction D2. A maximum width 760W of the recess 760 in the second direction D2 may be less than 2 times the maximum width 660W of the hole 660. The recesses 760 at the same level may be separated from each other by the insulating layer 4521. The recesses 760 at different levels may be separated from each other by the insulating layers 102. The sidewall ST2S of the second stack ST2 is exposed by the recess 760. The upper surface of the insulating layers 102, the lower surface of the insulating layers 102, the sidewall of the insulating layer 4521, and the sidewall of the insulating strip 4522 of the second stack ST2 are exposed by the recess 760. In an embodiment, a portion of the insulating layers 4521 is removed through a dry etching process or a wet etching process to form the recesses 760. For example, the dry etching process at this stage is a reactive ion etching (RIE) process. For example, the wet etching process at this stage is a wet etching process with phosphoric acid (H₃PO₄). In an embodiment, the dry etching process or the wet etching process used at this stage may remove a portion of the insulating film 101 exposed by the hole 660, so that the depth of the hole 660 in the first direction D1 is increased and the bottom 660B of the hole 660 is lower than the upper surface 101U of the insulating film 101 in the first direction D1, as shown in FIG. 7C. In other embodiments, the dry etching process or the wet etching process used at this stage may not change the depth of the hole 660 in the first direction D1, that is, the depth of the hole 660 in the first direction D1 after performing the steps illustrated with reference to FIGS. 7A to 7C is identical to the depth of the hole 660 in the first direction D1 before performing the steps illustrated with reference to FIGS. 7A to 7C.

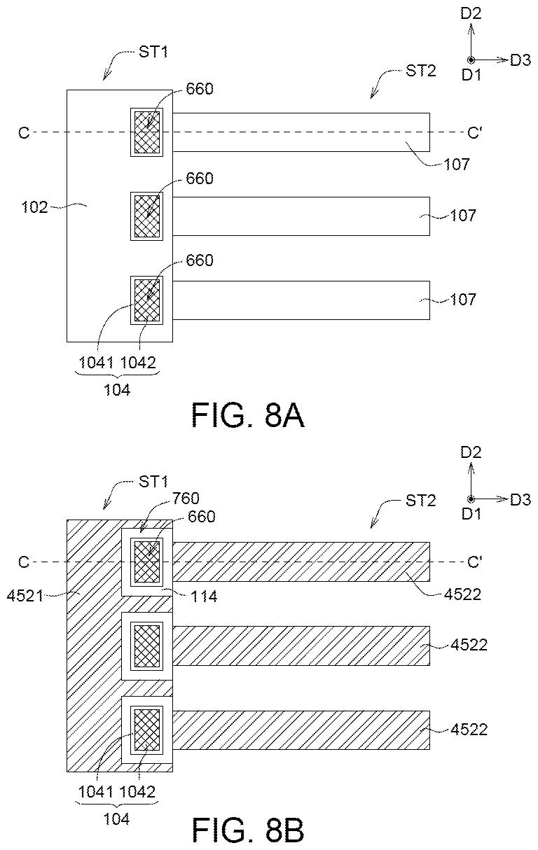

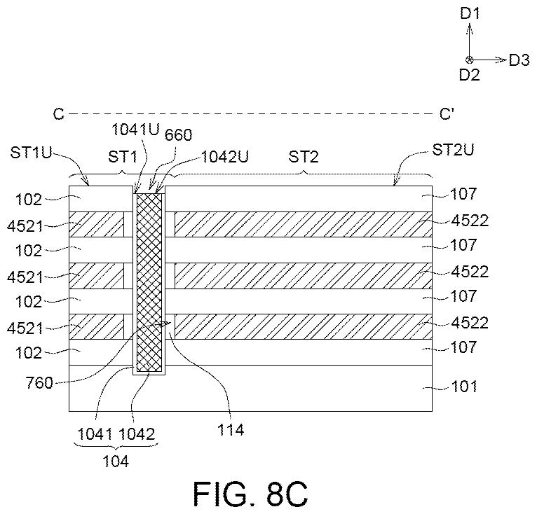

Referring to FIGS. 8A to 8C, FIG. 8A illustrates a schematic top view of a structure at a stage of the manufacturing method, FIG. 8B illustrates a schematic top view of the structure, corresponding to a plane of an insulating layer 4521 and an insulating strip 4522, at this stage of the manufacturing method, and FIG. 8C is a cross-sectional view of the structure at this stage illustrated along the lines CC′ shown in FIGS. 8A to 8B. Channel elements 114 and gate structures 104 are formed in the first stack ST1. The gate structure 104 includes a dielectric layer 1041 and a gate pillar 1042. Each of the channel elements 114 is formed in the recess 760. The channel element 114 fills the recess 760. Each of the gate pillars 1042 and each of the dielectric layers 1041 are formed in the hole 660. The channel element 114 may include an oxide semiconductor material, polycrystalline silicon, silicon germanium (SiGe), germanium, or any combination thereof. For example, the oxide semiconductor material is Indium oxide (InOₓ) and/or indium gallium zinc oxide (IGZO). The dielectric layer 1041 may include a dielectric material including oxide, for example, the dielectric layer 1041 includes silicon oxide, hafnium (IV) oxide (HfO₂) or Zirconium oxide (ZrOₓ). The gate pillar 1042 may include tantalum nitride (TaN), titanium nitride (TiN), tungsten (W), cobalt (Co), ruthenium (Ru), or any combination thereof. The gate pillar 1042 may have a multi-layer structure including titanium nitride/tungsten. In an embodiment, the channel elements 114 are formed in the recesses 760 through a deposition process; the channel elements 114 are formed on the upper surfaces of the insulating layers 102, the lower surfaces of the insulating layers 102, the sidewalls of the insulating layers 4521 and the sidewalls of the insulating strips 4522 of the second stack ST2 exposed by the recesses 760; next, the dielectric layers 1041 are formed in the holes 660; the dielectric layers 1041 are formed on the sidewalls of the insulating layers 102, the sidewalls of the channel elements 114, and the insulating film 101 exposed by the holes 660; the gate pillars 1042 are then formed in the in the remaining spaces of the holes 660 through a deposition process. In the first direction D1, an upper surface 1041U of the dielectric layer 1041 and an upper surface 1042U of the gate pillar 1042 may be lower than an upper surface ST1U of the first stack ST1 and an upper surface ST2U of the second stack ST2, but the present disclosure is not limited thereto.

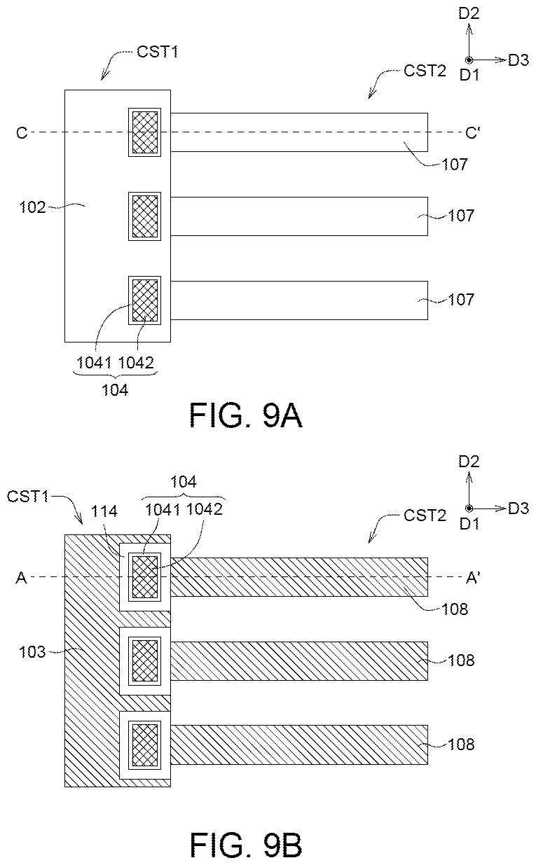

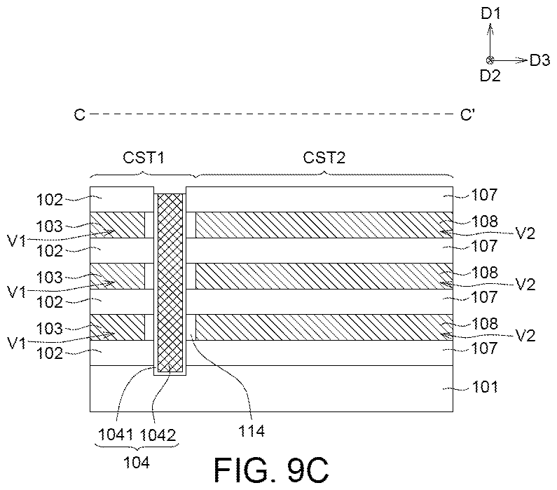

Referring to FIGS. 9A to 9C, FIG. 9A illustrates a schematic top view of a structure at a stage of the manufacturing method, FIG. 9B illustrates a schematic top view of the structure, corresponding to a plane of an conductive layer 103 and an conductive strip 108, at this stage of the manufacturing method, and FIG. 9C is a cross-sectional view of the structure at this stage illustrated along the lines CC′ shown in FIGS. 9A to 9B. Conductive layers 103 and conductive strips 108 are formed. The conductive layers 103 are between the insulating layers 102 and the channel elements 114. The conductive strips 108 are between the insulating strips 107 and the channel elements 114. The conductive layer 103 and the conductive strip 108 may include conductive materials including tungsten, doped or undoped silicon, titanium nitride, or any combination thereof. The conductive layer 103 and the conductive strip 108 may include the same material or different materials. In an embodiment, a selectively etching process is performed to remove the insulating layer 4521 and form spaces V1 and to remove the insulating strips 4522 to form spaces V2; the insulating layers 102, the insulating strips 107 and the insulating film 101 are retained during the etching process; the upper surfaces of the insulating layers 102, the lower surfaces of the insulating layers 102, and the sidewalls of the channel elements 114 are exposed by the spaces V1; the upper surfaces of the insulating strips 107, the lower surfaces of the insulating strips 107, and the sidewalls of the channel elements 114 are exposed by the spaces V2; then, the conductive layers 103 are formed to fill the spaces V1 and the conductive strips 108 are formed to fill the spaces V2 through a deposition process. A first conductive stack CST1 and second conductive stacks CST2 are formed. The first conductive stack CST1 includes the insulating layers 102 and the conductive layers 103 stacked alternately along the first direction D1. Each of the second conductive stacks CST2 includes the insulating strips 107 and the conductive strips 108 stacked alternately along the first direction D1. The second conductive stacks CST2 are on the sidewall of the first conductive stack CST1 and disposed along the second direction D2.

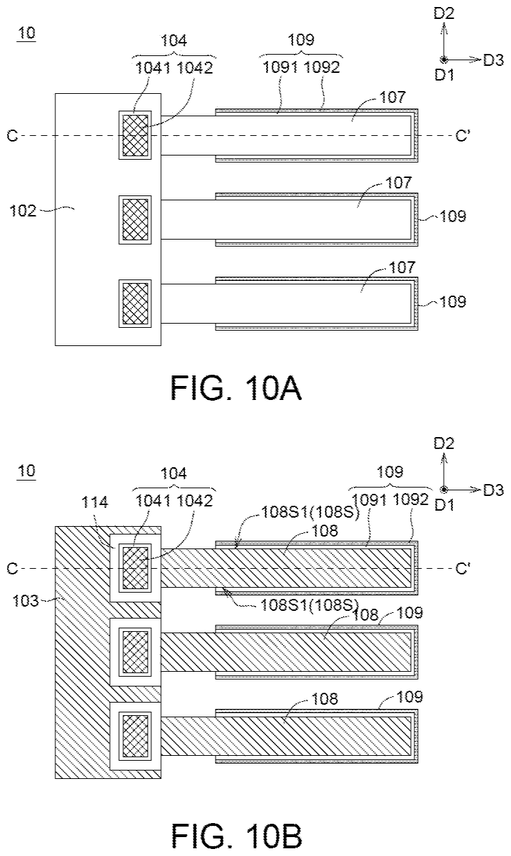

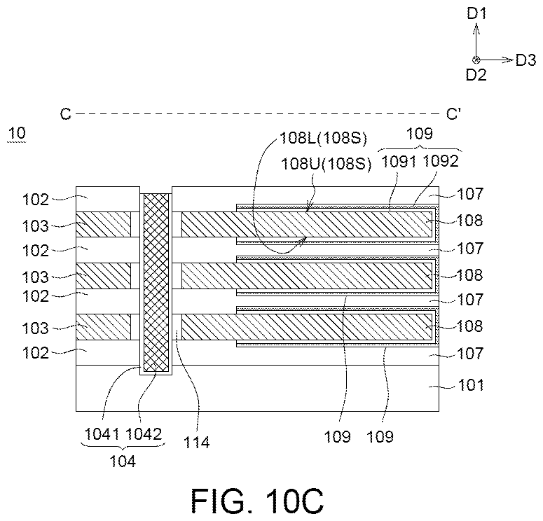

Referring to FIGS. 10A to 10C, FIG. 10A illustrates a schematic top view of a structure at a stage of the manufacturing method, FIG. 10B illustrates a schematic top view of the structure, corresponding to a plane of a conductive layer 103 and a conductive strip 108, at this stage of the manufacturing method, and FIG. 10C is a cross-sectional view of the structure at this stage illustrated along the lines CC′ shown in FIGS. 10A to 10B. Charge storage structures 109 are formed. The charge storage structure 109 and the channel element 114 may be respectively at opposite ends of the conductive strip 108 along the third direction D3. The charge storage structure 109 may be on the surface 108S of the conductive strip 108. The surface 108S of the conductive strip 108 at least includes an upper surface 108U, a lower surface 108L, a first sidewall 108S1 and a second sidewall 108S2. The upper surface 108U of the conductive strip 108 is opposite to the lower surface 108L of the conductive strip 108. The first sidewall 108S1 of the conductive strip 108 is opposite to the second sidewall 108S2 of the conductive strip 108. In the present embodiment, each of the charge storage structures 109 covers a portion of the upper surface 108U, a portion of the lower surface 108L, a portion of the first sidewall 108S1 and a portion of the second sidewall 108S2. The charge storage structure 109 surrounds or covers an end portion of the conductive strip 108 away from the channel element 114. A portion of the charge storage structure 109 may be between the conductive strip 108 and the insulating strip 107. In an embodiment, a portion of the insulating strips 107 and/or a portion of the conductive strips 108 are removed through a dry etching process or a wet etching process, and dielectric elements 1091 and conductive elements 1092 are sequentially formed on the surfaces of the conductive strips 108 through a deposition process to form the charge storage structure s 109. The dielectric element 1091 may include a material with a high dielectric constant (high-k dielectric), such as ZrO, ZrAlO, ZrNbO, ZrHfO, or any combination thereof. The dielectric element 1091 may have a multi-layer structure; for example, the dielectric element 1091 may be a ZrO/ZrAlO multi-layer structure or a ZrNbO/ZrHfO/ZrAlO multi-layer structure. The conductive element 1092 may include a conductive material including titanium nitride (TiN), tantalum nitride (TaN), titanium (Ti), cobalt (Co), tungsten (W), aluminum (AI), ruthenium (Ru), platinum (Pt), cobalt disilicide (CoSi₂) or any combination thereof.

In an embodiment, through the method schematically illustrated in FIGS. 4A to 10C, a semiconductor structure 10 is provided.

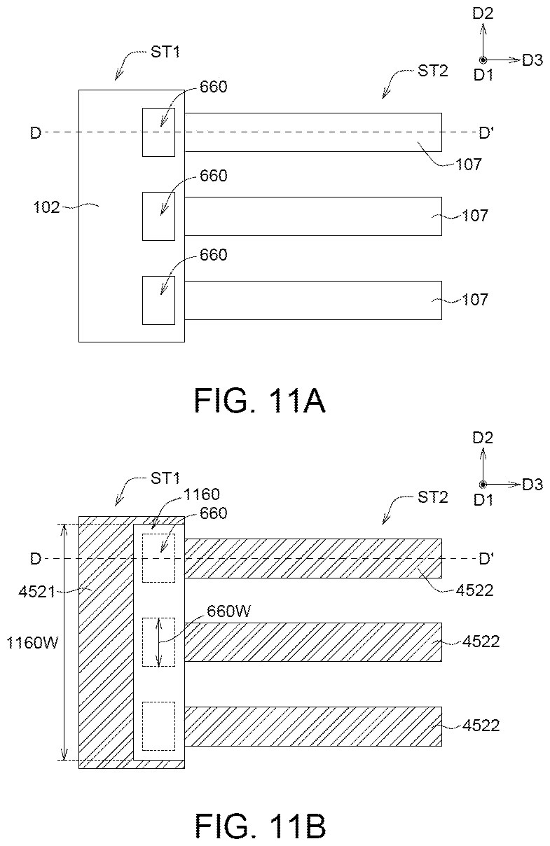

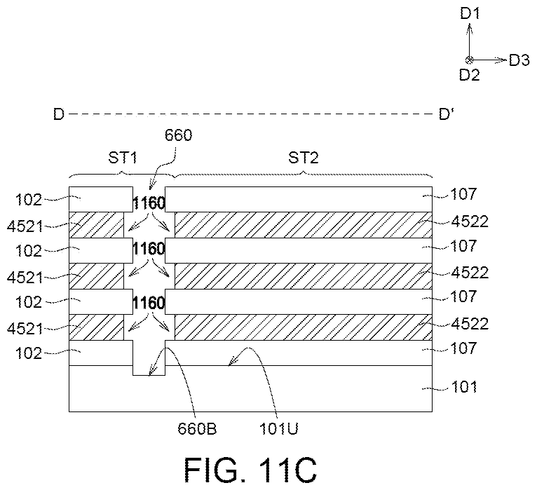

FIGS. 11A to 14C illustrate a method for manufacturing a semiconductor structure according to another embodiment of the present disclosure. In an embodiment, the manufacturing steps illustrated with reference to FIGS. 11A to 14C can be performed after the manufacturing steps illustrated with reference to FIGS. 4A to 6C.

Referring to FIGS. 11A to 11C, FIG. 11A illustrates a schematic top view of a structure at a stage of the manufacturing method, FIG. 11B illustrates a schematic top view of the structure, corresponding to a plane of an insulating layer 4521 and an insulating strip 4522, at this stage of the manufacturing method, and FIG. 11C is a cross-sectional view of the structure at this stage illustrated along the lines DD′ shown in FIGS. 11A to 11B. A portion of the insulating layers 4521 is removed to form recesses 1160. The recesses 1160 are disposed apart from each other along the first direction D1. The recesses 1160 are between the insulating layers 102. Each of the recesses 1160 communicate with the holes 660 at the same level as the recess 1160. A maximum width 1160W of the recess 1160 in the second direction D2 may be greater than a maximum width 660W of the hole 660 in the second direction D2. A maximum width 1160W of the recess 1160 in the second direction D2 may be greater than 2 times the maximum width 660W of the hole 660. In the present embodiment, the maximum width 1160W of the recess 1160 in the second direction D2 is greater than 3 times the maximum width 660W of the hole 660. In an embodiment, the maximum width 1160W of the recess 1160 in the second direction D2 depends on the number of gate structures 104 to be disposed; when the number of gate structures 104 to be disposed is n, the maximum width 1160W is greater than the maximum width 660W×n. The sidewall ST2S of the second stack ST2 is exposed by the recess 1160. The upper surface of the insulating layers 102, the lower surface of the insulating layers 102, the sidewall of the insulating layer 4521, and the sidewall of the insulating strip 4522 of the second stack ST2 are exposed by the recess 1160. Each of the recesses 1160 exposes the sidewalls of the insulating strips 4522 at the same level as the recess 1160. In an embodiment, a portion of the insulating layers 4521 is removed through a dry etching process or a wet etching process to form the recesses 1160. For example, the dry etching process at this stage is a reactive ion etching (RIE) process. For example, the wet etching process at this stage is a wet etching process with phosphoric acid (H₃PO₄). In an embodiment, the dry etching process or the wet etching process used at this stage may remove a portion of the insulating film 101 exposed by the hole 660, so that the depth of the hole 660 in the first direction D1 is increased and the bottom 660B of the hole 660 is lower than the upper surface 101U of the insulating film 101 in the first direction D1, as shown in FIG. 11C. In other embodiments, the dry etching process or the wet etching process used at this stage may not change the depth of the hole 660 in the first direction D1, that is, the depth of the hole 660 in the first direction D1 after performing the steps illustrated with reference to FIGS. 11A to 11C is identical to the depth of the hole 660 in the first direction D1 before performing the steps illustrated with reference to FIGS. 11A to 11C.

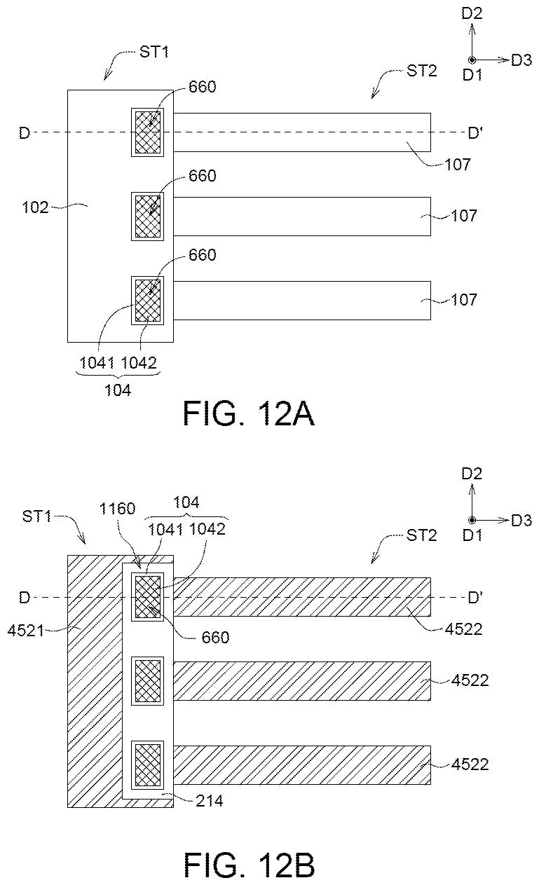

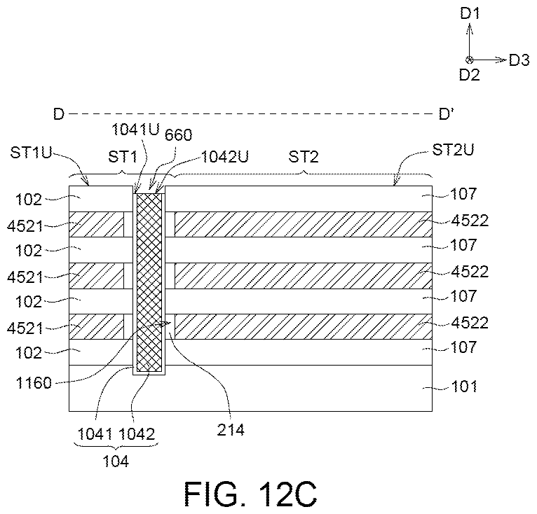

Referring to FIGS. 12A to 12C, FIG. 12A illustrates a schematic top view of a structure at a stage of the manufacturing method, FIG. 12B illustrates a schematic top view of the structure, corresponding to a plane of an insulating layer 4521 and an insulating strip 4522, at this stage of the manufacturing method, and FIG. 12C is a cross-sectional view of the structure at this stage illustrated along the lines DD′ shown in FIGS. 12A to 12B. Channel elements 214 and gate structures 104 are formed in the first stack ST1. The gate structure 104 includes a dielectric layer 1041 and a gate pillar 1042. Each of the channel elements 214 is formed in the recess 1160. The channel element 214 fills the recess 1160. Each of the gate pillars 1042 and each of the dielectric layers 1041 are formed in the hole 660. The channel element 214 may include an oxide semiconductor material, polycrystalline silicon, silicon germanium (SiGe), germanium, or any combination thereof. For example, the oxide semiconductor material is Indium oxide (InOₓ) and/or indium gallium zinc oxide (IGZO). In an embodiment, the channel elements 214 are formed in the recesses 1160 through a deposition process; the channel elements 214 are formed on the upper surfaces of the insulating layers 102, the lower surfaces of the insulating layers 102, the sidewalls of the insulating layers 4521 and the sidewalls of the insulating strips 4522 of the second stack ST2 exposed by the recesses 1160; next, the dielectric layers 1041 are formed in the holes 660; the dielectric layers 1041 are formed on the sidewalls of the insulating layers 102, the sidewalls of the channel elements 214, and the insulating film 101 exposed by the holes 660; the gate pillars 1042 are then formed in the in the remaining spaces of the holes 660 through a deposition process. In the first direction D1, an upper surface 1041U of the dielectric layer 1041 and an upper surface 1042U of the gate pillar 1042 may be lower than an upper surface ST1U of the first stack ST1 and an upper surface ST2U of the second stack ST2, but the present disclosure is not limited thereto.

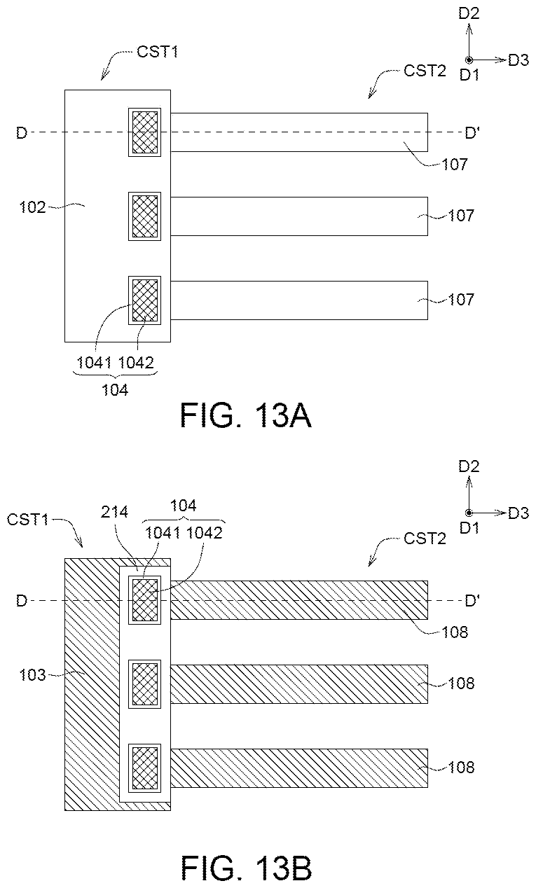

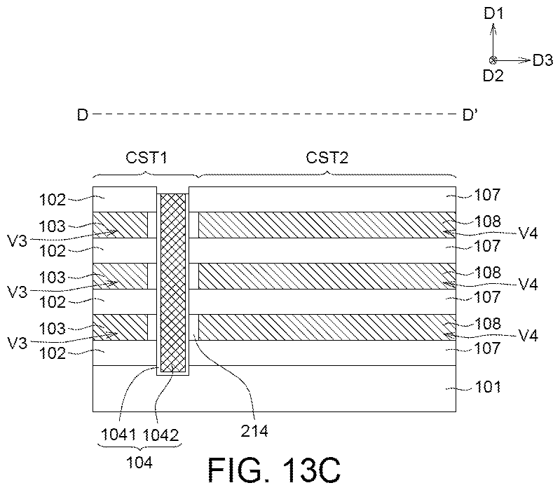

Referring to FIGS. 13A to 13C, FIG. 13A illustrates a schematic top view of a structure at a stage of the manufacturing method, FIG. 13B illustrates a schematic top view of the structure, corresponding to a plane of a conductive layer 103 and a conductive strip 108, at this stage of the manufacturing method, and FIG. 13C is a cross-sectional view of the structure at this stage illustrated along the lines DD′ shown in FIGS. 13A to 13B. Conductive layers 103 and conductive strips 108 are formed. The conductive layers 103 are between the insulating layers 102 and the channel elements 214. The conductive strips 108 are between the insulating strips 107 and the channel elements 214. In an embodiment, a selectively etching process is performed to remove the insulating layer 4521 and form spaces V3 and to remove the insulating strips 4522 to form spaces V4; the insulating layers 102, the insulating strips 107 and the insulating film 101 are retained during the etching process; the upper surfaces of the insulating layers 102, the lower surfaces of the insulating layers 102, and the sidewalls of the channel elements 214 are exposed by the spaces V3; the upper surfaces of the insulating strips 107, the lower surfaces of the insulating strips 107, and the sidewalls of the channel elements 214 are exposed by the spaces V4; then, the conductive layers 103 are formed to fill the spaces V3 and the conductive strips 108 are formed to fill the spaces V4 through a deposition process. A first conductive stack CST1 and second conductive stacks CST2 are formed. The first conductive stack CST1 includes the insulating layers 102 and the conductive layers 103 stacked alternately along the first direction D1. Each of the second conductive stacks CST2 includes the insulating strips 107 and the conductive strips 108 stacked alternately along the first direction D1. One channel element 214 contacts the conductive strips 108 at the same level as the channel element 214.

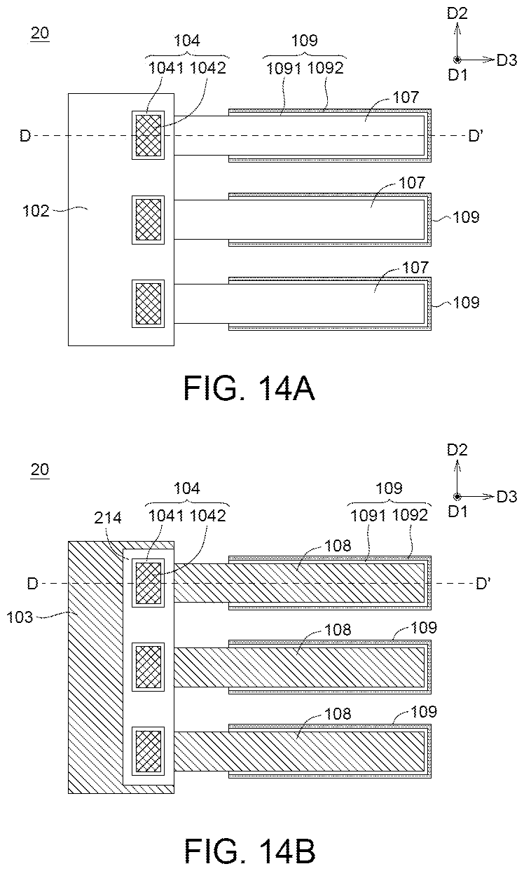

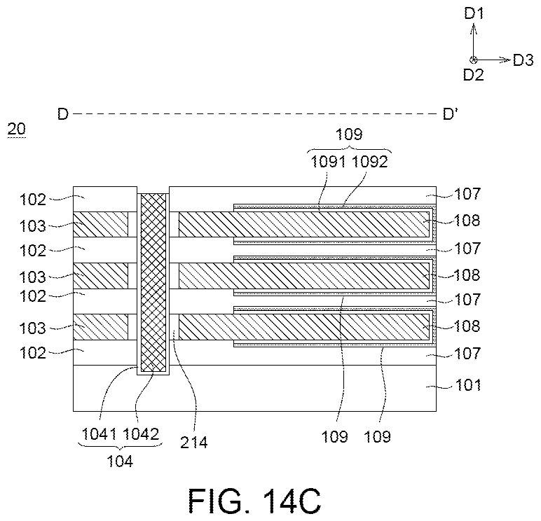

Referring to FIGS. 14A to 14C, FIG. 14A illustrates a schematic top view of a structure at a stage of the manufacturing method, FIG. 14B illustrates a schematic top view of the structure, corresponding to a plane of a conductive layer 103 and a conductive strip 108, at this stage of the manufacturing method, and FIG. 14C is a cross-sectional view of the structure at this stage illustrated along the lines DD′ shown in FIGS. 14A to 14B. Charge storage structures 109 are formed. The charge storage structure 109 and the channel element 214 may be respectively at opposite ends of the conductive strip 108 along the third direction D3. The structure, configuration, manufacturing method and material of the charge storage structure 109 may be similar to those described with reference to FIGS. 10A to 10C.

In an embodiment, through the method schematically illustrated in FIGS. 11A to 14C, a semiconductor structure 20 is provided.

The method for manufacturing the semiconductor structure according to the present disclosure uses a stack structure (such as the stack structure ST) including oxide (such as the insulating layer 451) and nitride (such as the insulating layer 452) to form the semiconductor structure. As compared with a comparative example, which uses a stack structure including silicon and silicon germanium to form a semiconductor structure, the stack structure including oxide and nitride used in the present disclosure is easy to etch and is suitable for use in a reactive ion etching (RIE) process, especially easy to perform a reactive ion etching (RIE) process. Therefore, using the method for manufacturing the semiconductor structure according to the present disclosure can simplify the manufacturing process. Furthermore, in the semiconductor structure and the method for manufacturing the semiconductor structure according to the present disclosure, the channel element (such as the channel element 114/214) includes Indium oxide (InOₓ) and/or indium gallium zinc oxide (IGZO), which can reduce the leakage problem of the capacitor, improve the electrical performance, reliability and yield of the semiconductor structure. Moreover, in the semiconductor structure and the method for manufacturing the semiconductor structure according to the present disclosure, the gate structure (such as the gate structure 104) penetrates the conductive layers. As compared with a comparative example in which the gate structure does not penetrate the conductive layers, the arrangement of the gate structure and the conductive layers of the present disclosure is easy to manufacture and can avoid electrical problems caused by gate structures contacting each other. Moreover, the semiconductor structure of the present disclosure can easily increase the number of memory cells per unit area by increasing the number of stacked layers, thereby forming a three-dimensional semiconductor structure with high integration density and excellent electrical performance.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
conductive layers;
a first gate pillar penetrating the conductive layers;
a first channel element surrounding the first gate pillar;
a first conductive strip on a sidewall of the first channel element; and
a charge storage structure on a surface of the first conductive strip.

2. The semiconductor structure according to claim 1, further comprising:
a second gate pillar penetrating the conductive layers, wherein the first gate pillar is separated from the second gate pillar;
a second channel element surrounding the second gate pillar, wherein the first channel element is separated from the second channel element.

3. The semiconductor structure according to claim 2, wherein the conductive layers are disposed along a first direction and extend along a second direction perpendicular to the first direction, the first gate pillar and the second gate pillar are disposed along the second direction, and the first channel element and the second channel element are in the conductive layers.

4. The semiconductor structure according to claim 3, further comprising:
a third channel element surrounding the first gate pillar, wherein the first channel element is separated from the third channel element.

5. The semiconductor structure according to claim 1, further comprising:
a second gate pillar penetrating the conductive layers, wherein the first gate pillar is separated from the second gate pillar, and the first channel element surrounds the first gate pillar and the second gate pillar.

6. The semiconductor structure according to claim 5, further comprising:
a second conductive strip on a sidewall of the first channel element.

7. The semiconductor structure according to claim 6, wherein the first conductive strip and the second conductive strip are at the same level.

8. The semiconductor structure according to claim 1, wherein the conductive layers are functioned as bit lines.

9. The semiconductor structure according to claim 1, further comprising:
a dielectric layer surrounding the first gate pillar and between the first gate pillar and the first channel element.

10. The semiconductor structure according to claim 1, further comprising:
a memory cell comprising a transistor and a capacitor, wherein the transistor forms at an intersection of the conductive layers and the first conductive strip, and the first conductive strip and the charge storage structure forms the capacitor.

11. The semiconductor structure according to claim 1, wherein the first channel element comprises an oxide semiconductor material.

12. The semiconductor structure according to claim 11, wherein the first channel element comprises first channel element comprises Indium oxide (InOₓ) and/or indium gallium zinc oxide (IGZO).

13. A method for manufacturing a semiconductor structure, comprising:
forming a first stack and s second stack, wherein the second stack is on a sidewall of the first stack;
forming a channel element in the first stack;
forming a gate pillar in the first stack, wherein the channel element surrounds the gate pillar;
forming bit lines, wherein the gate pillar penetrating the bit lines;
forming a conductive strip on a sidewall of the channel element; and
forming a charge storage structure on a surface of the conductive strip.

14. The method according to claim 13, further comprising:
forming a hole in the first stack;
forming a recess is the first stack, wherein the recess and the hole communicates with each other,
wherein the channel element is formed in the recess, and the gate pillar is formed in the hole.

15. The method according to claim 14, wherein the recess exposes the second stack.

16. The method according to claim 14, wherein the first stack comprises first insulating layers and second insulating layers stacked alternately, and the recess is between the first insulating layers

17. The method according to claim 16, wherein the hole penetrates the first insulating layers and the second insulating layers.

18. The method according to claim 16, wherein the first insulating layers comprise oxide, and the second insulating layers comprise nitride.

19. The method according to claim 13, further comprising:
forming a plurality of the gate pillars in the first stack, wherein the channel element surrounds the plurality of the gate pillars;

20. The method according to claim 13, wherein the channel element comprises an oxide semiconductor material.
